(19) United States
(12) Patent Application Publication
(10) Pub. No.: US 2026/0153811 A1
(43) Pub. Date: Jun. 4, 2026

(54) SUBSTRATE PROCESSING APPARATUS

(71) Applicant: SEMES CO., LTD., Cheonan-si (KR)

(72) Inventors: Ji Young CHOI, Hwaseong-si (KR); Ki Hoon LIM, Bucheon-si (KR); Sung Gyu LEE, Suwon-si (KR); A Rah CHO, Daejeon (KR); Jun Ho KIM, Seongnam-si (KR)

(21) Appl. No.: 19/339,761

(22) Filed: Sep. 25, 2025

(30) Foreign Application Priority Data
Dec. 4, 2024 (KR) 10-2024-0178675

(51) Int. Cl. G03F 7/00; G03F 7/16

(52) U.S. Cl. CPC G03F 7/70916; G03F 7/168; G03F 7/70858

(57) ABSTRACT

An embodiment of the present disclosure provides a substrate processing apparatus including a processing chamber having a processing space provided therein, and including a gas-supply unit introducing gas into the processing space; a support portion disposed in the processing space and supporting a substrate; a heating unit disposed to be spaced apart from an upper side of the support portion in the processing space, and including a lamp portion including a plurality of lamps heating the substrate, and a window disposed between the lamp portion and the support portion; and a discharge unit disposed to reciprocate in one direction between the support portion and the heating unit, and suctioning and discharging gas in the processing space.

### CROSS-REFERENCE TO RELATED APPLICATION(S)

This application claims benefit of priority to Korean Patent Application No. 10-2024-0178675 filed on Dec. 4, 2024 in the Korean Intellectual Property Office, the disclosure of which is incorporated herein by reference in its entirety.

### BACKGROUND

### 1. Field

The present disclosure relates to a substrate processing apparatus.

### 2. Description of Related Art

In order to manufacture a semiconductor device, a predetermined pattern should be formed on a substrate such as a wafer. When the predetermined pattern is formed on the substrate, a deposition process, a lithography process, an etching process, or the like may be continuously performed. Among such processes, a UV baking facility may be used to remove an organic material present between the fine patterns before performing the etching process after performing the lithograph process.

A UV baking process may be a method of heating a substrate while irradiating UV light thereto, a UV lamp may be present on an upper end of a wafer, and a baking chamber may have an inlet through which reaction gas is supplied, an exhaust port through which reaction gas is discharged, and a quartz member dividing the baking chamber and a lamp housing.

Here, since a position of the inlet and a position of the exhaust port may be fixed, there may be a problem that it is difficult to uniformly contact the reaction gas throughout the substrate. That is, a portion of the substrate adjacent to the inlet may be in contact with the reaction gas, a reaction for removing an organic film (organic material) may occur well. On the other hand, the other portion of the substrate far from the inlet (close to the exhaust port) may not be only difficult to contact the reaction gas, but also there may be a problem that the reaction for removing an organic film may not occur uniformly because gas and foreign substances that have already reacted may be mixed with the reaction gas.

### SUMMARY

The purpose of the present disclosure is to provide a substrate processing apparatus not only facilitating contact between a substrate and reaction gas, but also uniformly contacting the reaction gas with an entire surface of the substrate to effectively remove an organic film (organic material) present on the substrate.

To accomplish the purpose, a substrate processing apparatus according to an embodiment of the present disclosure includes a processing chamber having a processing space provided therein, and including a gas-supply unit introducing gas into the processing space; a support portion disposed in the processing space and supporting a substrate; a heating unit disposed to be spaced apart from an upper side of the support portion in the processing space, and including a lamp portion including a plurality of lamps heating the substrate, and a window disposed between the lamp portion and the support portion; and a discharge unit disposed to reciprocate in one direction between the support portion and the heating unit, and suctioning and discharging gas in the processing space.

A substrate processing apparatus according to another embodiment of the present disclosure includes a processing chamber having a processing space provided therein, and including a gas-discharging unit discharging gas in the processing space; a support portion disposed in the processing space and supporting a substrate; a heating unit disposed to be spaced apart from an upper side of the support portion in the processing space, and including a lamp portion including a plurality of lamps heating the substrate, and a window disposed between the lamp portion and the support portion; and an injection unit disposed to reciprocate in one direction between the support portion and the heating unit, and injecting gas into the processing space.

A substrate processing apparatus according to another embodiment of the present disclosure includes a processing chamber having a processing space provided therein, and including a gas-supply unit introducing gas into the processing space; a support portion disposed in the processing space and supporting a substrate; a heating unit disposed to be spaced apart from an upper side of the support portion in the processing space, and including a lamp portion including a plurality of lamps heating the substrate, and a window disposed between the lamp portion and the support portion; a discharge unit disposed to reciprocate in one direction between the support portion and the heating unit to discharge gas into the processing space, and including a body portion having a length, equal to or greater than a diameter of the substrate, and provided with a plurality of injection ports injecting the gas on a lower surface of the body portion, a supply line connected to the plurality of injection ports and discharging suctioned gas externally, and a driver providing power reciprocating the body portion; and a controller controlling the heating unit to heat the substrate, and controlling the discharge unit to discharge the gas in the processing space, wherein the processing space includes an upper space in which the lamp portion is disposed, and a lower space separated from the upper space and in which the substrate is disposed therein to perform a processing process for the substrate, the upper space and the lower space are at least partially partitioned by the window, the gas-supply unit is located between the discharge unit and the substrate, and at least two gas-supply units are provided to be disposed on both sides of the substrate, the plurality of injection ports are disposed on a lower surface of the body to form at least one row, and the controller controls, during heating the substrate by the lamp portion, the discharge unit to be disposed and wait on one side of the substrate, and when the heating of the substrate is completed, the discharge unit to reciprocate between both sides of the substrate in the one direction, suction gas to form an upstream in the lower space, and introduce a new gas into the processing space through the gas-supply unit, to generate convection between the substrate and the upper space to remove by-products generated during the heating of the substrate.

### BRIEF DESCRIPTION OF DRAWINGS

The and other aspects, features, and advantages of the present disclosure will be more clearly understood from the following detailed description, taken in conjunction with the accompanying drawings, in which:

FIG. 1 is a view of a substrate processing apparatus according to an embodiment of the present disclosure, viewed from above.

FIG. 2 is a view of the substrate processing apparatus of FIG. 1, viewed in direction A-A.

FIG. 3 is a view of the substrate processing apparatus of FIG. 1, viewed in direction B-B.

FIG. 4 is a cross-sectional view schematically illustrating a substrate processing apparatus according to an embodiment of the present disclosure.

FIG. 5 schematically illustrates a lower surface of a discharge unit according to an embodiment of the present disclosure.

FIG. 6 schematically illustrates a lower surface of a discharge unit according to another embodiment of the present disclosure.

FIG. 7 schematically illustrates a lower surface of a discharge unit according to another embodiment of the present disclosure.

FIG. 8 schematically illustrates a lower surface of a discharge unit according to another embodiment of the present disclosure.

FIG. 9 is a cross-sectional view illustrating a state in which a discharge unit is disposed in an initial position, in the substrate processing apparatus of FIG. 1.

FIG. 10 illustrates a state in which a discharge unit is disposed in a discharge position to discharge gas, in the substrate processing apparatus of FIG. 1.

FIG. 11 illustrates a view of a discharge unit according to an embodiment of the present disclosure, viewed from above.

FIG. 12 illustrates a view of a discharge unit according to another embodiment of the present disclosure, viewed from above.

FIG. 13 is a cross-sectional view of a substrate processing apparatus according to another embodiment of the present disclosure, illustrating a state before an injection unit is disposed in an initial position to inject gas.

FIG. 14 is an example illustrating a state in which an injection unit is disposed in an injection position to inject gas in the substrate processing apparatus of FIG. 13.

### DETAILED DESCRIPTION

Hereinafter, preferred embodiments may be described in detail with reference to the accompanying drawings such that those skilled in the art may easily implement the present disclosure. However, in describing the preferred embodiment of the present disclosure in detail, when it is determined that a detailed description of a related known function or configuration may unnecessarily obscure the gist of the present disclosure, the detailed description thereof may be omitted. In addition, the same reference numerals may be used throughout the drawings for components that perform similar functions and actions. In addition, in the present specification, terms such as ‘on,’ ‘upper portion,’ ‘upper side,’ ‘upward,’ ‘upward direction,’ ‘upper surface,’ ‘upper wall,’ ‘below,’ ‘lower portion,’ ‘lower side,’ ‘downward,’ ‘downward direction,’ ‘lower surface,’ ‘lower wall,’ or the like may be based on the drawings, and terms such as ‘in,’ ‘into,’ ‘internal portion’ ‘out of,’ ‘outside of,’ ‘external portion’ or the like may be based on an outer periphery of a component of interest, and may be actually changed, depending on a direction in which an element or a component is disposed.

In addition, throughout the specification, being able to ‘comprise’ or ‘include’ a component may mean that another component may be further included rather than excluding another component unless specifically opposed thereto.

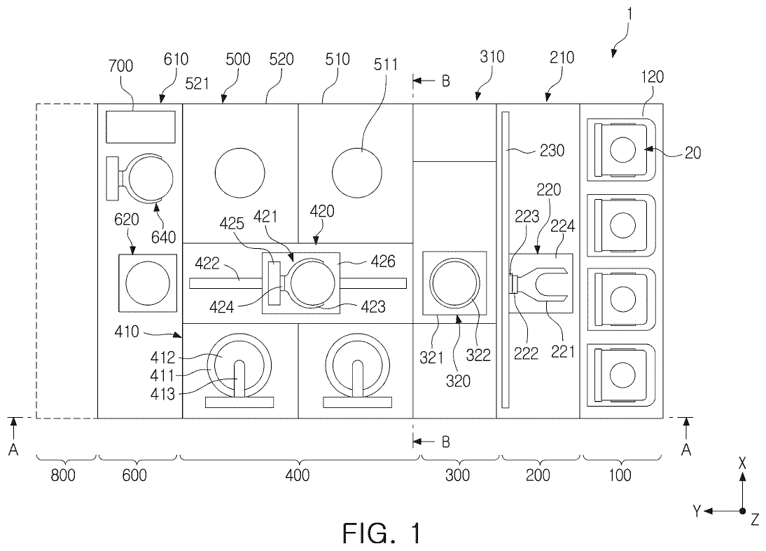

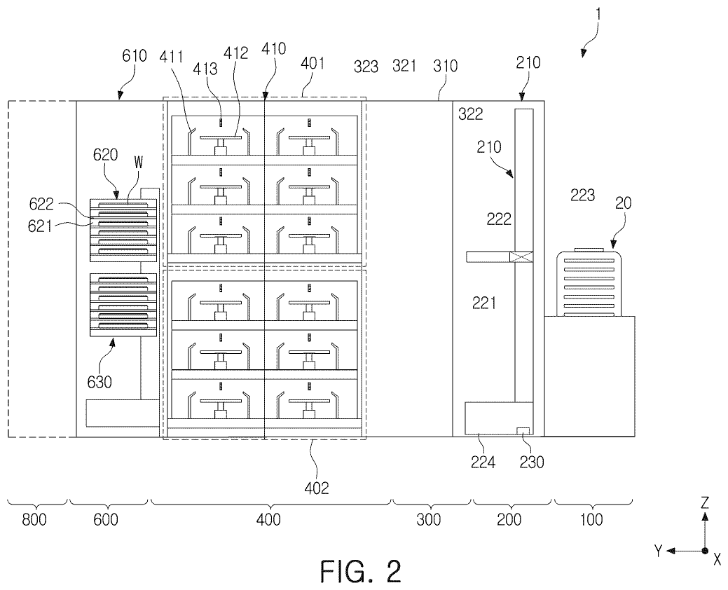

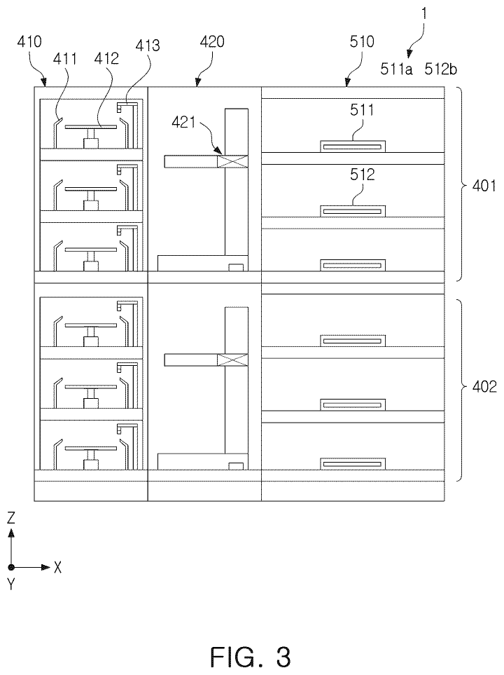

FIG. 1 is a view of a substrate processing apparatus according to an embodiment of the present disclosure, viewed from above, FIG. 2 is a view of the substrate processing apparatus of FIG. 1, viewed in direction A-A, and FIG. 3 is a view of the substrate processing apparatus of FIG. 1, viewed in direction B-B.

Referring to FIGS. 1 to 3, a substrate processing apparatus 1 may include a loading port 100, an index module 200, a buffer module 300, an applying/development module 400, and a purge module 700. The loading port 100, the index module 200, the buffer module 300, the applying/development module 400, and an interface module 600 may be sequentially disposed in a line in one direction. The purge module 700 may be provided in the interface module 600. Alternatively, the purge module 700 may be provided at various positions such as a position to which an exposure device 800 at a rear end of the interface module 600 is connected, a side portion of the interface module 600, or the like. Hereinafter, a direction in which the loading port 100, the index module 200, the buffer module 300, the applying/development module 400, and the interface module 600 are disposed may be referred to as a first direction Y, and, when viewed from above, a direction, perpendicular to the first direction Y, may be referred to as a second direction X, and a direction, perpendicular to each of the first and second directions Y and X may be referred to as a third direction Z.

A substrate W may be moved in a state accommodated in a cassette 20. The cassette 20 may have a structure that may be sealed from the outside. For example, a front opening unified pod (FOUP) having a door in a front portion may be used as the cassette 20.

Hereinafter, the loading port 100, the index module 200, the buffer module 300, the applying/development module 400, the interface module 600, and the purge module 700 will be described in detail.

The loading port 100 may include a mounting table 120 on which the cassette 20 in which the substrate W is accommodated is disposed. The mounting table 120 may be provided as a plurality of mounting tables 120, and the mounting tables 120 may be disposed in a row in the second direction X. Although FIG. 2 illustrates an example in which four mounting tables 120 are provided, the number thereof may be changed.

The index module 200 may transfer the substrate W between the buffer module 300 and the cassette 20 disposed on the mounting table 120 of the loading port 100. The index module 200 may include a frame 210, an index robot 220, and a guide rail 230.

The frame 210 may be provided in a rectangular parallelepiped shape having an empty internal portion, and may be disposed between the loading port 100 and the buffer module 300. The frame 210 of the index module 200 may be provided at a lower height than a frame 310 of the buffer module 300.

The index robot 220 and the guide rail 230 may be disposed within the frame 210. The index robot 220 may be provided such that a hand 221 directly handling the substrate W is movable and rotated in the first direction Y, the second direction X, and the third direction Z. The index robot 220 may include a hand 221, an arm 222, a support 223, and a base 224. The hand 221 may be fixedly installed on the arm 222. The arm 222 may be provided in a stretchable structure and a rotatable structure. The support 223 may be disposed such that a length direction of the support 223 is in the third direction Z. The arm 222 may be coupled to the support 223 to be movable along the support 223. The support 223 may be fixedly coupled to the base 224. The guide rail 230 may be provided such that a length direction thereof is in the second direction X. The base 224 may be coupled to the guide rail 230 to be linearly movable along the guide rail 230. Also, although not illustrated, the frame 210 may be further provided with a door opener to open or close a door of the cassette 20.

The buffer module 300 may include a frame 310, a first buffer 320, a second buffer 330, and a cooling chamber 340. The frame 310 may be provided in a rectangular parallelepiped shape having an empty internal portion, and may be disposed between the index module 200 and the applying/development module 400. The first buffer 320, the second buffer 330, and the cooling chamber 340 may be located in the frame 310. The cooling chamber 340, the second buffer 330, and the first buffer 320 may be sequentially disposed from below in the third direction Z. The first buffer 320 may be located at a height corresponding to an application module 401 of the applying/development module 400, and the second buffer 330 and the cooling chamber 340 may be provided at a height corresponding to a development module 402 of the applying/development module 400.

The first buffer 320 and the second buffer 330 may temporarily store a plurality of substrates W, respectively. The first buffer 320 may have a housing 321 and a plurality of supports 322. In the first buffer 320, the supports 322 may be disposed in the housing 321, and may be provided to be spaced apart from each other in the third direction Z. The second buffer 330 may include a housing 331 and a plurality of supports 332. In the second buffer 330, the supports 332 may be disposed in the housing 331, and may be spaced apart from each other in the third direction Z. One substrate W may be located in each of the supports 322 of the first buffer 320 and each of the supports 332 of the second buffer 330. The housing 331 may have an opening in a direction in which the index robot 220 is provided such that the index robot 220 carries the substrate W in or out of the support 332 in the housing 331.

The first buffer 320 may have a structure substantially similar to a structure of the second buffer 330. The housing 321 of the first buffer 320 may have an opening in a direction in which the first buffer robot 360 is provided and in a direction in which an application unit robot 421 located in the application module 401 is provided. The number of supports 322 provided in the first buffer 320 may be the same or different from the number of supports 332 provided in the second buffer 330. According to an example, the number of supports 332 provided in the second buffer 330 may be greater than the number of supports 322 provided in the first buffer 320.

Cooling chambers 340 may cool the substrate W, respectively. The cooling chamber 340 may include a housing 341 and a cooling plate 342. The cooling plate 342 may have an upper surface on which the substrate W is disposed, and a cooling means 343 cooling the substrate W. As the cooling means 343, various methods such as cooling by cooling water, cooling by using a thermoelectric element, or the like may be used. Also, the cooling chamber 340 may be provided with a lift pin assembly positioning the substrate W on the cooling plate 342. The housing 341 may have an opening in a direction in which the index robot 220 is provided and in a direction in which the developing unit robot is provided such that a developing unit robot provided in the index robot 220 and the developing module 402 may carry the substrate W in or out of the cooling plate 342. Also, doors configured to open and close the above-described openings may be provided in the cooling chamber 340.

Although the buffer module 300 has been described in an embodiment including a configuration of the cooling chamber 340, the present disclosure is not limited thereto, and a configuration of the cooling chamber 340 may be omitted as necessary.

The application module 401 may include a process of applying a photosensitive solution such as a photoresist to the substrate W, and a heat processing process such as heating and cooling the substrate W before and after a resist coating process. The application module 401 may include an application chamber 410, a heat treatment chamber portion 500, and a transfer chamber 420. The application chamber 410, the transfer chamber 420, and the heat treatment chamber portion 500 may be sequentially disposed in the second direction X. For example, with respect to the transfer chamber 420, the application chamber 410 may be provided on one side of the transfer chamber 420, and the heat treatment chamber portion 500 may be provided on the other side of the transfer chamber 420.

The application chamber 410 may be provided as a plurality of application chambers 410, and the plurality of application chambers 410 may be provided, respectively, in the third direction Z. Also, as illustrated in FIG. 1, the application chamber 410 may be provided in plural or as one, in the first direction Y.

The heat treatment chamber portion 500 may include a baking chamber 510 and a cooling chamber 520, and the baking chamber 510 and the cooling chamber 520 may be provided in plural, respectively, in the third direction Z. The transfer chamber 420 may be located in parallel in the first direction Y with the first buffer 320 of the buffer module 300. The application unit robot 421 and the guide rail 422 may be located in the transfer chamber 420. The transfer chamber 420 may have a substantially rectangular shape. The application unit robot 421 may transfer the substrate W between the baking chamber 510, the cooling chamber 520, the application chamber 410, and the first buffer 320 of the buffer module 300.

The guide rail 422 may be disposed such that a length direction thereof is parallel to the first direction Y. The guide rail 422 may guide the application unit robot 421 to move linearly in the first direction Y. The application unit robot 421 may have a hand 423, an arm 424, a support 425, and a base 426. The hand 423 may be fixedly installed on the arm 424. The arm 424 may be provided in a stretchable structure such that the hand 423 moves in a horizontal direction. The support 425 may be provided such that a length direction thereof is disposed in the third direction Z. The arm 424 may be coupled to the support 425 to be linearly movable in the third direction Z along the support 425. The support 425 may be fixedly coupled to the base 426, and the base 426 may be coupled to the guide rail 422 to be movable along the guide rail 422.

All of the application chambers 410 may have the same structure, but types of processing liquids used in each application chamber 410 may be different from each other. As a processing liquid, a processing liquid for forming a photoresist film or an antireflection film may be used.

The application chamber 410 may apply a processing liquid onto the substrate W. A processing unit including a processing container 411, a support portion 412, and a nozzle portion 413 may be provided in the application chamber 410.

For example, one processing unit may be disposed in each application chamber 410 in the first direction Y, but the present disclosure is not limited thereto, and two or more processing units may be disposed in one application chamber 410. All of the processing units may have the same structure. However, types of processing liquids used in each of the processing units may be different from each other. The processing container 411 of the application chamber 410 may have a shape in which an upper portion is opened. The support portion 412 may be disposed in the processing container 411, and may support the substrate W. The support portion 412 may be rotatably provided. The nozzle portion 413 may supply the processing liquid onto the substrate W disposed on the support portion 412. The processing liquid may be applied to the substrate W in a spin-coat manner. Additionally, the application chamber 410 may be optionally provided with a nozzle (not illustrated) supplying a cleaning liquid such as deionized water (DIW) to clean a surface of the substrate W to which the processing liquid is applied, and a back rinse nozzle (not illustrated) to clean a lower surface of the substrate W.

The baking chamber 510 may heat the substrate W, when the substrate W is seated by the application unit robot 421. In the baking chamber 510, a pre-bake process of heating the substrate W by a predetermined temperature, before applying a processing liquid, to remove organic matter or moisture from a surface of the substrate W, a soft bake process performed after applying a processing liquid on the wafer W, or the like may be performed. In addition, after a heating process is performed in the baking chamber 510, a cooling process for cooling the substrate W, or the like, may be performed.

A heating plate 511 and a heating means 511a may be provided in the baking chamber 510.

The heating means 511a may heat the substrate W disposed in the baking chamber 510. In this case, the substrate W may be heated in a state in which the baking chamber 510 is sealed, and the heating means 511a may heat an entire region of the substrate W to a uniform temperature. As the heating means 511a, for example, a heating method using a heating wire provided inside or outside the heating plate 511 may be used.

In addition, a heating method using a device such as a heater or the like disposed inside or outside the baking chamber 510 may be used. For example, the baking chamber 510 may be equipped with a lamp portion 910 irradiating light such as ultraviolet rays or the like to the upper surface of the substrate W to heat the substrate W, which will be described in detail below.

Such a heat processing process may blow an organic material onto a liquid film formed by applying the processing liquid on the substrate W, to stabilize the liquid film.

Furthermore, the baking chamber 510 may further include a chilling plate (not illustrated). The chilling plate may include at least one cooling means for cooling the substrate W. The chilling plate may cool the substrate W by receiving cooling water from a cooling unit 910 to be described later. Therefore, it is possible to prevent the substrate W from being heated to an excessively high temperature due to the heat processing process. The substrate W on which the heat processing process is completed may be transported to the cooling chamber 520.

In the cooling chamber 520, a cooling process of cooling the substrate W may be performed before applying the processing liquid. The cooling chamber 520 may include a chilling plate. The chilling plate may be a cooling means for cooling the substrate W, and various methods such as cooling by cooling water, cooling using a thermoelectric element, or the like may be used.

The interface module 600 may connect the applying/development module 400 to an exposure device 800 externally. The interface module 600 may include an interface frame 610, a first interface buffer 620, a second interface buffer 630, and a transfer robot 640, and the transfer robot 640 may return a substrate returned to the first and second interface buffers 620 and 630 to the exposure device 800, after an operation of the applying/development module 400 is completed. The first interface buffer 620 may include a housing 621 and a support 622, and the transfer robot 640 and the application unit robot 421 may load/unload the substrate W into/out the support 622.

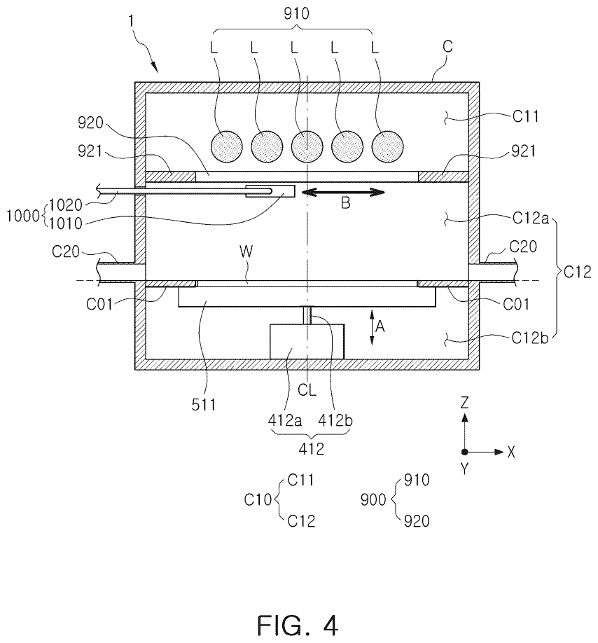

FIG. 4 is a cross-sectional view schematically illustrating a substrate processing apparatus according to an embodiment of the present disclosure.

Referring to FIG. 4, a substrate processing apparatus 1 according to an embodiment (hereinafter, referred to as Example 1) of the present disclosure may include a processing chamber C, a support portion 412, a heating unit 900, and a discharge unit 1000.

The processing chamber C may have a processing space C10 therein. A substrate W may be supplied to the processing space C10 to perform a processing process on the substrate W. More specifically, a heat processing process on the substrate W may be performed in the processing space C10. In this case, the processing chamber C may be the baking chamber 510, described above.

The processing chamber C may include a gas-supply unit C20. The gas-supply unit C20 may be connected to an external gas-supplying device (not illustrated) to supply gas into the processing space C10. In this case, the supplied gas may include oxygen O₂ as processing gas for decomposing an organic material present on a surface of the substrate W. After the gas is supplied to the processing space C10, oxygen contained in the gas may meet light emitted from a lamp L to generate ozone O₃. An organic film (organic material) present on the substrate W may be decomposed by the ozone O₃ generated as described above.

The gas-supply unit C20 may be disposed at various positions of the processing chamber C. In an embodiment, the gas-supply unit C20 may be disposed in a sidewall portion of the processing chamber C. For example, two gas-supply units C20 may be provided. In this case, the two gas-supply units C20 may be disposed on both sidewalls of the processing chamber C, respectively. In this case, the two gas-supply units C20 may be disposed on both sides of the substrate W, with the substrate W disposed on the support portion 412 in the processing space C10 interposed therebetween. Therefore, the gas-supply units C20 may be disposed to face each other in the width direction X of the processing chamber C. Although the present disclosure is not limited to the embodiment, for convenience of description, embodiments in which two gas-supply units C20 are provided and disposed on both sides of the substrate W, as described above, will be mainly described.

The substrate W supplied into the processing space C10 may be seated on and supported on the support portion 412. In this case, the support portion 412 may be disposed in the processing space C10.

A plate may be disposed on an upper end of the support portion 412. The plate may be a portion supporting the substrate W, and may be a heating plate as described above. Hereinafter, the plate will be referred to as a heating plate 511. The heating plate 511 may include a heating means 511a heating the substrate W, which may be the same as or similar to the above-described description, and thus a redundant description will be omitted.

The heating plate 511 may include a plurality of support pins (not illustrated). The plurality of support pins may be formed to protrude upward (+Z) from an upper surface of the heating plate 511. The plurality of support pins may be supported after a lower surface of the substrate W is seated thereon.

The plurality of support pins may be provided to be raised or lowered from the heating plate 511. When a new substrate W is supplied to the support portion 412 or the heat-processed substrate W is discharged, the plurality of support pins may be raised. In this state, the substrate W may be transferred onto a support pin by an application unit robot 421 or the heat-processed substrate W may be discharged from the support pin. Thereafter, the support pin may be lowered again, and the transfer of the substrate W may be completed.

The support portion 412 may include a driving motor 412a and a driving shaft 412b. A lower end portion of the driving shaft 412b may be connected to the driving motor 412a. In addition, the heating plate 511 may be connected to an upper end portion of the driving shaft 412b. The driving shaft 412b may be raised or lowered by receiving power from the driving motor 412a. Therefore, the heating plate 511 coupled to the upper end portion of the driving shaft 412b may be raised or lowered in a lifting direction A.

The heating unit 900 may perform a heat treatment on the substrate W disposed in the processing space C10. In this case, the heating unit 900 may include a lamp portion 910 and a window 920. The lamp portion 910 may be configured to heat the substrate W, and may include a plurality of lamps L. For example, a lamp L may be a light source such as a UV lamp, and may irradiate light for heating the substrate W. In this case, the light may be ultraviolet rays having a wavelength of 10 to 300 nm.

The heating unit 900 may be disposed in an upper end portion of the processing space C10. More specifically, the processing space C10 may include an upper space C11 and a lower space C12. The upper space C11 and the lower space C12 may be spaces separated from each other, and the window 920 may be disposed between the upper space C11 and the lower space C12.

The lower space C12 may be divided into a first lower space C12a, which may be an upper region of the substrate W, and a second lower space C12b, which may be a lower region of the substrate W, based on the substrate W (or the upper surface of the substrate W) supported on the support portion 412. In this case, the first lower space C12a and the second lower space C12b may be separated by the heating plate 511 and a partition wall portion C01 extending from an edge portion of the heating plate 511 to an inner side wall of the lower space C12. Also, the gas-supplying portion C20 may be disposed above the partition wall portion C01 and the second lower space C12b. Therefore, while the heat treatment on the substrate W is performed, gas such as processing gas or the like may be supplied only to the first lower space C12a, and may be discharged to the outside of the processing chamber C without being introduced into the second lower space C12b.

The lamp portion 910 may be disposed in the upper space C11. The plurality of lamps L may be spaced apart from each other at predetermined intervals in a width direction X in the upper space C11. The plurality of lamps L may be disposed to extend side by side. For example, an extension direction Y of the lamp L may be a direction, perpendicular to the width direction X described above.

The window 920 may be disposed under the lamp portion 910. The window 920 may be the same as the lamp portion 910 or may be extended to have a length, longer than the lamp portion 910. For example, the window 920 may be formed of a quartz material.

The window 920 may be fixed to the inside of the processing space C10 in a state of being supported by a support 921 disposed to surround an external side in a circumferential direction thereof. For example, the support 921 may be provided to surround and support a periphery of the window 920, and may be fixedly coupled to an inner side surface of the processing space C10. The upper space C11 and the lower space C12 may be separated from each other by the window 920 and the support 921 surrounding the same.

The substrate W may be disposed in the lower space C12. More specifically, the support portion 412 may be disposed below the window 920. For example, the support portion 412 may be disposed to share a virtual center line CL with the window 920. On the support portion 412 disposed in this manner, the substrate W to be heat treated may be supported.

In this case, light (ultraviolet rays) emitted from the plurality of lamps L may pass through the transparent window 920 and move to the first lower space C12a. In the first lower space C12a, oxygen contained in the gas (processing gas) may meet light to generate ozone. By the ozone generated as described above, the organic film (organic material) present on a surface of the substrate W may be decomposed and removed from the substrate W. In addition, some of the light that has moved to the first lower space C12a may be irradiated to the surface of the substrate W to directly decompose some of the organic film (organic material).

In a process of decomposing the organic film (organic material) as described above, various types of by-products may be generated in the first lower space C12a. As the by-products, for example, CO₂, H₂O, or the like may be included. Such by-products may be discharged to the outside of the processing space C10 by the discharge unit 1000, which will be described later.

The discharge unit 1000 may discharge gas in the processing space C10 externally. The discharge unit 1000 may be disposed between the support portion 412 and the heating unit 900.

More specifically, the discharge unit 1000 may be disposed in the lower space C12. For example, the discharge unit 1000 may be disposed on an upper end of the lower space C12 or directly below the window 920. In this case, the discharge unit 1000 may reciprocate in a transfer direction B between both sides of the window 920, based on the width direction X described above. In this case, the transfer direction B may be a direction, parallel to the width direction X of the processing chamber C. To this end, the discharge unit 1000 may include a driver (not illustrated). Although not illustrated in the drawing, the driver may be configured as a linear motor or the like to provide power for the discharge unit 1000 to move.

More specifically, the discharge unit 1000 may be located below the window 920, and is movable by reciprocating between one side of the window 920 (or one side of the support 921) and the other side of the window 920 (or the other side of the support 921). As a result, light emitted from the lamp L may not be prevented from being irradiated to the substrate W by waiting in a state disposed on one side (a standby position to be described later) of the window 920 (a first state T1 to be described later) while the heat treatment on the substrate W is in progress.

The discharge unit 1000 may include a body portion 1010 and a discharge line 1020. In this case, the body portion 1010 may be provided with a suction port H. The discharge line 1020 may be connected to the suction port H. More specifically, one end of the discharge line 1020 may be connected to the suction port H through the body portion 1010. In addition, the other end of the discharge line 1020 may extend to the outside of the processing chamber C. In this case, the gas in the processing space C10 may be suctioned through the suction port H, and may then be discharged to the outside of the processing chamber C through the discharge line 1020. In this case, a pump (not illustrated) suctioning gas or the like may be connected to the discharge line 1020 to provide suction power suctioning and discharging the gas.

The suction port H may be disposed in a lower surface of the body portion 1010. The discharge unit 1000 may be disposed above the support portion 412, and thus the lower surface of the body portion 1010 may face an upper surface of the substrate W supported by the support portion 412. At least one suction port H may be provided. For example, a plurality of suction ports H may be provided, and hereinafter, the plurality of suction ports H will be described based on a plurality of individual embodiments, but the present disclosure is not limited thereto.

The body portion 1010 may have a length, equal to or longer than a diameter of the substrate W which may be a heat treatment target. Therefore, the upper surface of the substrate W may be entirely covered by the body portion 1010 while the body portion 1010 passes through the upper portion of the substrate W in the transfer direction B.

Further, the substrate treating apparatus 1 may further include a controller (not illustrated). The controller may be electrically connected to the heating unit 900 to control the heating unit 900 to heat-treat the substrate W. Further, the controller may be electrically connected to the discharging unit 1000 to discharge gas in the processing space C10 externally.

The controller may be implemented in a form of, for example, a circuit board mounted on a control computer of the substrate processing apparatus 1, a computer chip mounted on the circuit board, software built into the computer chip or built into the control computer, or the like. In this case, a specific method of controlling the heating unit 900 and the discharge unit 1000 will be described later.

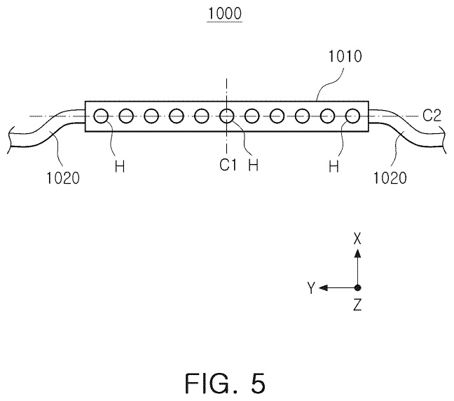

FIG. 5 schematically illustrates a lower surface of a discharge unit according to an embodiment of the present disclosure.

Referring to FIG. 5, in a discharge unit 1000 according to an embodiment of the present disclosure (hereinafter, Example 1), a plurality of suction ports H may be disposed in a line in a length direction Y of a body portion 1010. In this case, the length direction Y may be a direction, perpendicular to a transfer direction B of the discharge unit 1000 and parallel to an extension direction Y of a lamp L, as described above. For example, the plurality of suction ports H may be disposed in a line along a virtual center line C2 passing through a center of the body portion 1010 and extending parallel to the extension direction Y.

In addition, in the discharge unit 1000 according to Example 1, the plurality of suction ports H may have the same or similar diameter.

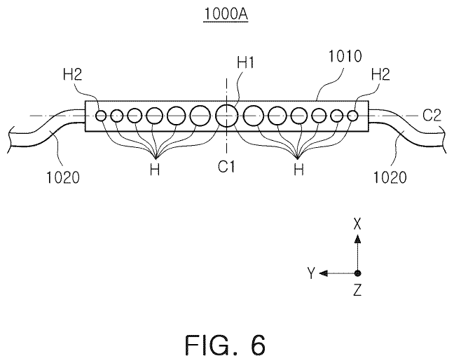

FIG. 6 schematically illustrates a lower surface of a discharge unit according to another embodiment of the present disclosure.

Referring to FIG. 6, in a discharge unit 1000A according to another embodiment of the present disclosure (hereinafter, referred to as Example 2), a plurality of suction ports H may be disposed in a line in a length direction Y of a body portion 1010. For example, a plurality of suction ports H may be disposed in a line along a virtual center line C2 passing through a center of the body portion 1010 and extending parallel to the extension direction Y.

In the discharge unit 1000A according to Example 2, diameters of the plurality of suction ports H may be changed in the extension direction Y of the body portion 1010. More specifically, a suction port H1 disposed in a central portion, among the plurality of suction ports H, may have the largest diameter. Diameters of the suction ports H may gradually decrease from the suction port H1 to the outside of the body portion 1010 in the extension direction Y. Therefore, diameters of suction ports H2 disposed at both ends of the body portion 1010 may be the smallest. As described above, the suction ports H, H1, and H2 may be connected to a discharge line 1020.

As the suction ports H, H1, and H2 are configured to gradually increase diameters toward a center of the body portion 1010, a flow rate per unit area of gas suctioned and discharged through the suction port H1 in the central portion of the body portion 1010, which may be a portion of the body portion 1010 overlapping the substrate W in the most degree when viewed from above, may be maximized. This may be advantageous for smooth discharge of gas.

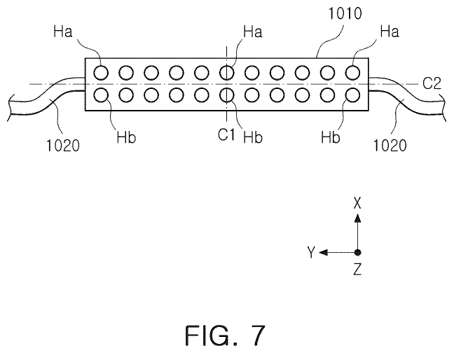

FIG. 7 schematically illustrates a lower surface of a discharge unit according to another embodiment of the present disclosure.

Referring to FIG. 7, a discharge unit 1000B according to another embodiment (hereinafter, referred to as Example 3) of the present disclosure may be disposed such that a plurality of suction ports Ha and Hb form a plurality of rows in a length direction Y of a body portion 1010.

For example, the suction ports Ha and Hb may be disposed on a lower surface of the body portion 1010 to form two rows. In this case, the suction port Ha in a first row and the suction port Hb in a second row may be symmetrically disposed, with a virtual center line C2 interposed therebetween. In this case, the plurality of suction ports Ha and Hb may have the same or similar diameter.

In the discharge unit 1000B according to Example 3, although not illustrated in the drawing, the suction port may be provided to form three or more rows on the lower surface of the body portion 1010. As another example, the suction ports may be provided in a form having different diameters while forming two or more rows, or the suction ports may be disposed to form a plurality of rows, but may deviate from each other. As described above, when the plurality of suction ports H are provided on the lower surface of the body portion 1010 to form at least two or more rows, a larger amount of gas may be suctioned and discharged during the same time period.

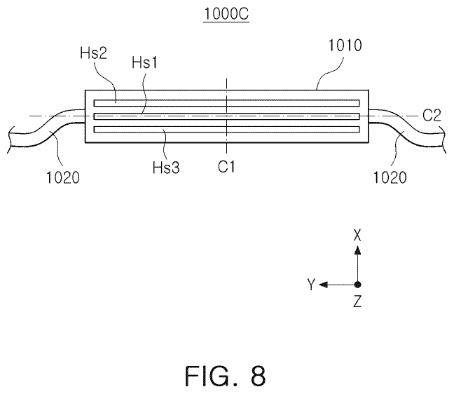

FIG. 8 schematically illustrates a lower surface of a discharge unit according to another embodiment of the present disclosure.

Referring to FIG. 8, a discharge unit 1000C according to another embodiment of the present disclosure (hereinafter, referred to as Example 4) may include suction ports Hs1, Hs2, and Hs3 in a slit shape. The suction ports Hs1, Hs2, and Hs3 may have an elongated slit shape extending in an extension direction Y of a body portion 1010. In this case, the suction ports Hs1, Hs2, and Hs3 may have a length, similar to a length of the body portion 1010.

At least one of the suction port Hs1, Hs2, or Hs3 may be provided. For example, three suction ports Hs1, Hs2, and Hs3 may be provided, and may be disposed side by side to extend in the extension direction Y of the body portion 1010. More specifically, any one suction port Hs1 may be disposed to at least partially overlap a virtual center line C2 described above. And, remaining two suction ports Hs2 and Hs3 may be symmetrically disposed in a width direction X, with the suction port Hs1 interposed therebetween. In this case, the suction ports Hs1, Hs2, and Hs3 may have the same or similar widths (lengths in an X-axis direction in the drawing).

The suction ports Hs1, Hs2, and Hs3 may have an open shape. In another embodiment, the suction ports Hs1, Hs2, and Hs3 may be provided with an opening/closing portion (not illustrated), respectively. The suction ports Hs1, Hs2, and Hs3 may be selectively opened and closed by the opening/closing portion. For example, the suction ports Hs1, Hs2, and Hs3 may be selectively opened only when internal gas of a processing space C10 is suctioned and discharged by the opening/closing portion. When the suction and discharging of the above-described gas are unnecessary, the suction ports Hs1, Hs2, and Hs3 may be closed by the opening/closing portion.

In the discharge unit 1000C according to Example 4, although not illustrated in the drawing, the above-described suction ports Hs1, Hs2, and Hs3 may have different widths. For example, the suction port Hs1 in a central portion may have the largest width, and the other two suction ports Hs2 and Hs3 may have a relatively small width. As another example, one or two slit-shaped suction ports may be provided.

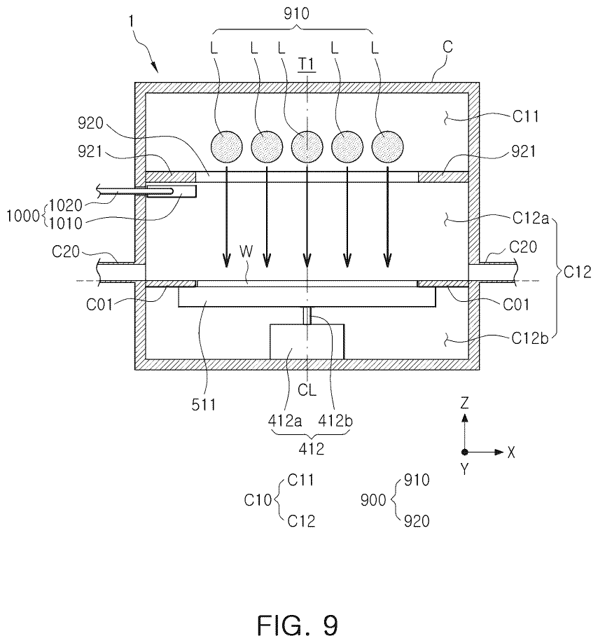

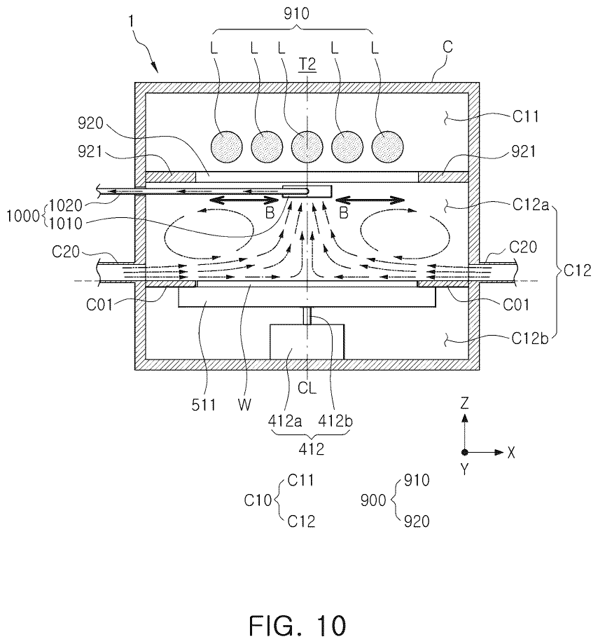

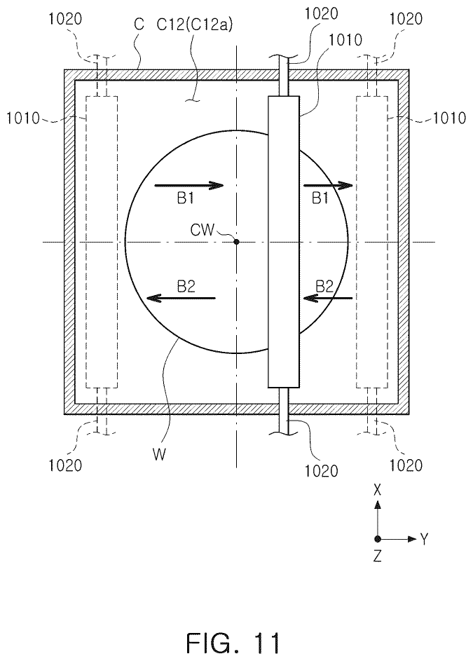

FIG. 9 is a cross-sectional view illustrating a state in which a discharge unit is disposed in an initial position, in the substrate processing apparatus of FIG. 1. FIG. 10 illustrates a state in which a discharge unit is disposed in a discharge position to discharge gas, in the substrate processing apparatus of FIG. 1. In addition, FIG. 11 illustrates a view of a discharge unit according to an embodiment of the present disclosure, viewed from above.

Referring to FIGS. 9 to 11, a method of forming an airflow for discharging gas in a processing space C10 and a foreign material included therein may be as follows when a substrate processing apparatus 1 according to Example 1 may be heat-processed on a substrate W.

First, during heat treatment on a substrate W, light emitted from a lamp L of a lamp portion 910 may pass through a window 920, and may be irradiated to the substrate W. Also, gas corresponding to processing gas may be supplied to a processing space C10 through a gas-supply unit C20. In this case, the gas may be supplied to a first lower space C12a.

Ozone may be generated by allowing light to meet oxygen contained in the gas in the first lower space C12a. An organic film (organic material) present on a surface (upper surface) of the substrate W may be decomposed and removed by the ozone generated as described above. In a process of decomposing the organic material, by-products may be generated, and the generated by-products may include CO₂, H₂O, or the like.

While the heat treatment on the substrate W is in progress, a discharge unit 1000 may be disposed at a “standby position” to wait. The standby position may be a position in which the discharge unit 1000 does not interfere with transmission of light emitted from the lamp L to the substrate W. The standby position may be a lower point of a portion of a support 921 disposed to surround the window 920. As illustrated in FIG. 9, the standby position may be a point directly below the left (based on the drawing) portion of the window 920, among the support 921.

As described above, a state in which the discharge unit 1000 is disposed at the standby position and heat treatment is performed on the substrate W may be defined as a ‘first state T1.’

When the heat treatment for the substrate W is completed in the first state T1, the discharge unit 1000 may suck and discharge the gas in the processing space C10. Therefore, pollutants contained in the gas may be discharged and removed to the outside of the processing space C10. Pollutants may cause a defect in the substrate W to decrease yield, and may include foreign substances such as by-products (e.g., CO₂, H₂O, or the like) generated by decomposition of the organic film (organic material) on the substrate W, as described above, and/or dust present in the processing space C10, or the like.

More specifically, the discharge unit 1000 may suck gas in a lower space C12 through a plurality of suction ports H formed in a lower surface of a body portion 1010. In this case, since the discharge unit 1000 sucks gas from an upper side of the substrate W, the gas on a lower side of the discharge unit 1000 may rise toward the discharge unit 1000. Therefore, an upstream may be formed in the lower space C12 (or a region between the discharge unit 1000 and the substrate W).

At the same time, a new gas may be supplied into the lower space C12 through the gas-supply unit C20 provided on both sides of the substrate W or a support portion 412. In this case, by the heat treatment of the substrate W, the gas in a periphery of the substrate W may be also raised, while the newly introduced gas may have a relatively low temperature. Due to a difference in temperature, the gas in a heated state may be raised, and in this process, the gas may be more actively raised by a suction operation of the discharge unit 1000. In addition, the newly introduced gas having a low temperature may be introduced into the periphery of the substrate W, which may be an empty space as the heated gas rises.

The gas raised toward the discharge unit 1000 may be suctioned through the suction ports H, and may then move along a discharge line 1020 to be discharged to the outside of a processing chamber C.

While the gas is suctioned and discharged as described above, the discharge unit 1000 may reciprocate and horizontally move in a transfer direction B from the upper side of the substrate W. While the discharge unit 1000 moves, the lamp L may be maintained in an off state. When the lamp L is in an on state, the discharge unit 1000 may be located on the left side of the window 920 (see FIG. 9) or on the right side of the window 920 (not illustrated). Thereby, the light L emitted by the lamp L may not be prevented from being irradiated to the substrate, and when the lamp L may be turned off, the discharge unit 1000 may move rapidly in a left or right direction to remove an organic material from the substrate W.

More specifically, the discharge unit 1000 may reciprocate from one side of the window 920 to the other side in the transfer direction B in the lower space C12. Therefore, a direction in which the gas rises may be changed to the left or right direction with respect to a central portion CL of the processing chamber C.

For example, when the discharge unit 1000 sucks gas while moving in a first transfer direction B1, which may be a direction facing the right from the central portion CL, the gas in the lower space C12 may also rise in an inclined direction to be gradually deflected toward the right. A portion of the gas that have risen in this manner may be suctioned and discharged by the discharge unit 1000. The other portion of the gas that have risen may not be suctioned into the discharge unit 1000, and may continue to rise. An upstream that has not been suctioned and discharged in this manner may be lowered again after hitting the support 921 or the window 920.

Therefore, convection may occur between the substrate W and the discharge unit 1000 in a right region of the lower space C12. In a similar manner, convection may occur in a left region of the lower space C12 due to rising and descending of the gas while the discharge unit 1000 sucks gas in a second transfer direction B2, which may be a direction toward the left side from the central portion CL.

As described above, a state in which the discharge unit 1000 reciprocates from an upper portion of the substrate W and sucks and discharges the gas in the processing space C10 may be defined as a ‘second state T2.’

In the second state T2, as the gas-supply unit C20 may be disposed at both side portions of the processing chamber C, gas, which may be processing gas, may be supplied to both sides of the substrate W. Therefore, an airflow in both directions toward a central portion CW of the substrate W may be formed from both sides of the substrate W. Therefore, compared to a case in which the gas-supply unit C20 is provided only on one side of the substrate W, the gas may be evenly supplied to the entire substrate W, and may be in contact with a surface of the substrate W.

In addition, an airflow in which gas circulates in a vertical direction may be generated in the first lower space C12a due to convection generated by reciprocating movement of the discharge unit 1000. In the first lower space C12a, in addition to the airflow in both directions to the substrate W, as described above, an area in which the gas (processing gas) is in contact with the surface of the substrate W may increase. As a result of these, excellent and uniform organic decomposition and removal effects may be obtained on the entire surface of the substrate W due to fixed gases such as ozone.

Although the embodiment in which one discharge unit 1000 is provided has been described, but the substrate processing apparatus 1 may include a plurality of discharge units 1000.

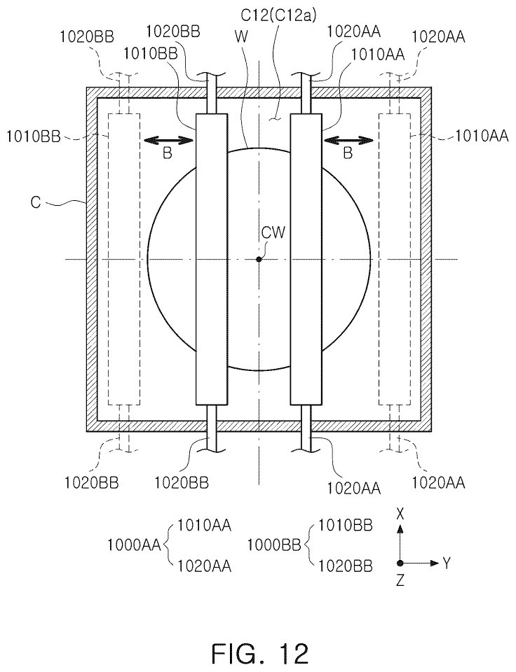

FIG. 12 illustrates a view of a discharge unit according to another embodiment of the present disclosure, viewed from above.

Referring to FIG. 12, a substrate processing apparatus 1 according to another embodiment of the present disclosure may include two discharge units 1000. In this case, for convenience of description, any one of the two discharge units 1000 will be defined as a first discharge unit 1000AA, and the other one of the two discharge units 1000 will be defined as a second discharge unit 1000BB.

In this case, the first discharge unit 1000AA may be disposed in a right region of a lower space C12, and the second discharge unit 1000BB may be disposed in a left region of the lower space C12. In this case, the right region may mean a space on a right side of the lower space C12, based on a center CW of a substrate W, and the left region may mean a space on a left side of the lower space C12, based on the center CW of the substrate W.

The first discharge unit 1000AA may reciprocate in a transfer direction B in the right region of the lower space C12. The first discharge unit 1000AA may suck gas in the right region of the lower space C12 to form an upstream and discharge the gas. At the same time, the first discharge unit 1000AA may reciprocate in the right region, and may suck gas, thereby generating convection in the right region during a gas-discharging process.

In addition, the second discharge unit 1000BB may reciprocate in the transfer direction B in the left region of the lower space C12. The second discharge unit 1000BB may suck gas in the left region of the lower space C12 to form an upstream and discharge the gas. At the same time, the second discharge unit 1000BB may suck gas while reciprocating in the left region, thereby generating convection in the left region during the gas-discharging process.

As described above, the lower space C12 may be virtually divided into at least two regions, and separate discharge units 1000AA and 1000BB may be installed for each of the virtual divided regions to suck and discharge gas. In this case, the gas may be more quickly discharged from the processing space C10 by the plurality of discharge units 1000AA and 1000BB.

In addition, convection may be generated in each of the virtual divided regions of the lower space C12, such that convection may occur more actively in the processing space C10. Therefore, by increasing a contact area between the processing gas for decomposing an organic material, such as ozone or the like, and the substrate W, an effect of decomposing the organic material may be further improved.

In addition, when the heat processing process (organic decomposition process) for any one of the substrates W is completed, a substrate W corresponding thereto may be discharged from the processing chamber C, and a new substrate W may be supplied to the processing chamber C. In this case, even while the substrate W is replaced, the discharge unit 1000 may continuously reciprocate in the transfer direction B, and may suck and discharge the gas in the processing space C10. Therefore, contaminants present in the processing space C10 may be continuously discharged and removed while the substrate W may be replaced, thereby maintaining cleanliness of an internal portion of the processing chamber C even when the plurality of substrates W are continuously heat-treated. This may bring about an effect of improving yield of the substrate W.

On the other hand, the drawing illustrates only a case in which the substrate processing apparatus 1 includes two discharge units 1000A and 1000B, but the present disclosure is not limited thereto.

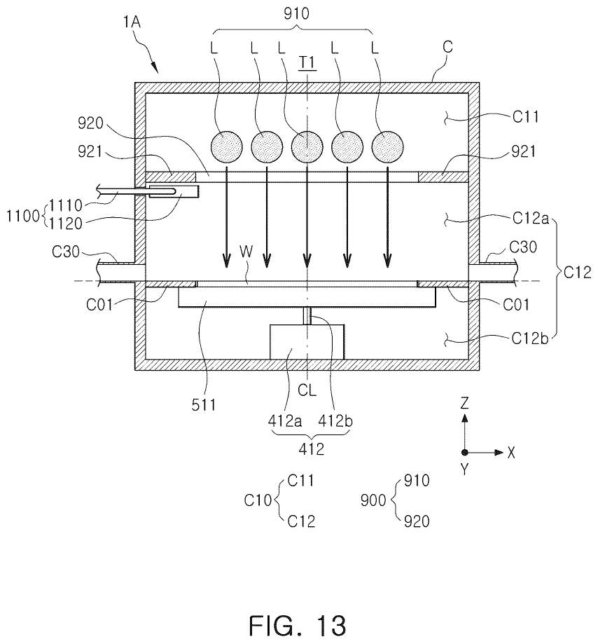

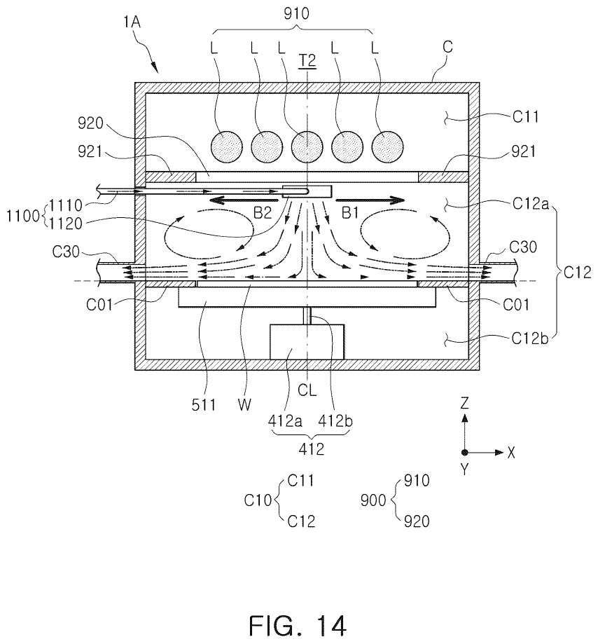

FIG. 13 is a cross-sectional view of a substrate processing apparatus according to another embodiment of the present disclosure, illustrating a state before an injection unit is disposed in an initial position to inject gas. Also, FIG. 14 is an example illustrating a state in which an injection unit is disposed in an injection position to inject gas in the substrate processing apparatus of FIG. 13.

Referring to FIGS. 13 and 14, a substrate processing apparatus 1A according to another embodiment of the present disclosure (hereinafter, referred to as Example 2) may include a processing chamber C, a support portion 412, a heating unit 900, and an injection unit 1100. Since detailed features of the processing chamber C, the support portion 412, and the heating unit 900 may be the same as or similar to those of the substrate processing apparatus 1 according to Example 1 described above, redundant descriptions will be omitted and differences will be mainly described.

Unlike Example 1, the substrate processing apparatus 1A according to Example 2 may include a gas-discharging unit C30 in a processing chamber C. The gas-discharging unit C30 may be a passage through which gas in a processing space C10 is discharged externally. The gas-discharging unit C30 may be disposed at various positions of a processing chamber C.

As an example, the gas-discharging unit C30 may be disposed on a sidewall portion of the processing chamber C. As an example, two gas-discharging units C30 may be provided. In this case, the two gas-discharging units C30 may be disposed on both sidewall portions of the processing chamber C, one by one. In this case, the two gas-discharging units C30 may be disposed on both sides of a substrate W, with the substrate W disposed on the support portion 412 in the processing space C10 interposed therebetween. Therefore, the gas-discharging units C30 may be disposed to face each other in a width direction X of the processing chamber C.

Although the present disclosure is not limited to the embodiment, for convenience of description, hereinafter, embodiments in which two gas-discharging units C30 are provided as described above, and are disposed on both sides of the substrate W, will be mainly described.

The injection unit 1100 may inject gas into the processing space C10. The injection unit 1100 may be disposed between the support portion 412 and the heating unit 900.

More specifically, the injection unit 1100 may be disposed in a lower space C12. For example, the injection unit 1100 may be disposed on an upper end of the lower space C12 or directly below a window 920. In this case, the injection unit 1100 may reciprocate in a transfer direction B between both sides of the window 920, based on the width direction X of the processing chamber C. To this end, the injection unit 1100 may include a driver (not illustrated). Although not illustrated in the drawings, the driver may be composed of a linear motor or the like, to provide power for the injection unit 1100 to move.

More specifically, the injection unit 1100 may reciprocate and move between one side of the window 920 (or one side of a support 921) and the other side of the window 920 (or the other side of the support 921) while the heat treatment on the substrate W is in progress, thereby not preventing light emitted from a lamp L from being irradiated to the substrate W (i.e., the first state T1).

The injection unit 1100 may include a body portion 1110 and a supply line 1120. In this case, the body portion 1110 may have an injection port (not illustrated) on a lower surface thereof. The supply line 1120 may be connected to the injection port. More specifically, one end portion of the supply line 1120 may be connected to the body portion 1110 by penetrating the same, and may be connected to the injection port. In addition, the other end portion of the supply line 1120 may extend to the outside of the processing chamber C. In this case, a pump (not illustrated) supplying gas may be connected to the other end portion of the supply line 1120. The gas supplied through the supply line 1120 may be injected into the processing space C10 through the injection port of the body portion 1110.

The injection port may be disposed in a lower surface of the body portion 1110. The injection unit 1100 may be disposed in the upper side of the support portion 412, and thus the lower surface of the body portion 1110 may face the upper surface of the substrate W supported by the support portion 412. At least one injection port may be provided. For example, a plurality of injection ports may be provided, and hereinafter, the plurality of injection ports will be described based on a plurality of individual embodiments, but the present disclosure is not limited thereto.

The injection port may be disposed in various forms. In this case, the injection port may be disposed in the lower surface of the body portion 1110 in the same or similar manner as the suction port H described above. For example, the plurality of injection ports may be disposed in the lower surface of the body portion 1110 to form a row or at least two rows in an extension direction Y. As another example, the plurality of injection ports may be provided in a form in which a diameter gradually increases toward the center of the body portion 1110, or as another example, at least one injection port having a slit shape may be provided.

Further, the substrate processing apparatus 1A may further include a controller (not illustrated). The controller may be electrically connected to the heating unit 900 to control the heating unit 900 to heat-treat the substrate W. Further, the controller may be electrically connected to the injection unit 1100 to inject (supply) gas into the processing space C10.

The controller may be implemented in a form of, for example, a circuit board mounted on a control computer of the substrate processing apparatus 1A, a computer chip mounted on the circuit board, software built into the computer chip or built into the control computer, or the like. In this case, a specific method of controlling the heating unit 900 and the injection unit 1100 will be described later.

Although not illustrated in the drawings, as another embodiment, the substrate processing apparatus may include both the discharge unit of Example 1 and the injection unit of Example 2. In this case, the discharge unit and the injection unit may be disposed above the substrate W in the first lower space C12a. In this case, the discharge unit and the injection unit reciprocate in the transfer direction B, and the gas in the first lower space C12a may be suctioned and discharged to the outside by the discharge unit. At the same time, gas may be supplied to the first lower space C12a by the injection unit. For example, gas (reaction gas) may be supplied and removed to the first lower space C12a.

Referring back to FIGS. 13 and 14, when the substrate processing apparatus 1A according to Example 2 heats the substrate W, a method of forming an airflow for discharging gas in the processing space C10 and foreign substances included therein to the outside may be as follows.

First, while the heat treatment on the substrate W is performed, the injection unit 1100 may wait while being disposed at a standby position. The standby position may be a position in which the injection unit 1100 does not interfere with transmission of light emitted from the lamp L to the substrate W, and for example, as illustrated in FIG. 13, may be a point immediately below the left (based on the drawing) portion of the window 920 among the supports 921, as described in Example 1. In this manner, a state in which the injection unit 1100 is disposed at the standby position and the heat treatment is performed on the substrate W may be defined as a ‘first state T1.’

When the heat treatment for the substrate W is completed in the first state T1, the injection unit 1100 may suck and discharge the gas in the processing space C10. Therefore, pollutants contained in the gas may be discharged and removed to the outside of the processing space C10. Pollutants may cause a defect in the substrate W to decrease yield, and may include foreign substances such as by-products generated by decomposition of the organic film on the substrate W, as described above, and/or dust present in the processing space C10, or the like.

More specifically, the injection unit 1100 may inject (supply) gas into the lower space C12 through the plurality of injection ports formed on the lower surface of the body portion 1110. In this case, since the injection unit 1100 injects gas from the upper side of the substrate W, the injected gas may be lowered toward the substrate W. As a result, a downstream may be formed in the lower space C12 (or a region between the injection unit 1100 and the substrate W).

At the same time, internal gas of the lower space C12 may be discharged to the outside through the gas-discharging unit C30 of the processing chamber C provided at both sides of the substrate W or the support portion 412. In this case, by the heat treatment of the substrate W, the gas at the periphery of the substrate W may be in a state in which the temperature may be raised, while the newly introduced gas may be in a state in which a temperature is relatively low. In this case, a portion of the gas that have been heated may be discharged. The other portion of the heated gas may not pass through the gas-discharging unit C30, and may rise again in the lower space C12 after hitting the inner surface of the processing chamber C.

The gas that has risen again may be lowered together with the new gas injected and supplied from the injection unit 1100 and be discharged to the outside of the processing chamber C through the gas-discharging unit C30. By partially cooling the temperature of the gas raised in this process, the gas may be lowered more smoothly.

While the gas is injected and discharged as described above, the injection unit 1100 may reciprocate and move horizontally in the transfer direction B from the upper side of the substrate W.

More specifically, the injection unit 1100 may reciprocate from one side of the window 920 to the other side in the transfer direction B in the lower space C12. Therefore, a direction in which the gas is lowered may be changed to a direction toward the left or right direction with respect to the center CL of the processing chamber C.

For example, when the injection unit 1100 injects gas while moving to the right from the central portion CL along the first transfer direction B1, the gas in the lower space C12 may be also lowered in an inclined direction to be gradually deflected toward the right. A portion of the gas that have lowered in this manner may be discharged through the gas-discharging unit C30. The other portion of the gas that have fallen may not pass through the gas-discharging unit C30, and may collide with the inner surface of the processing chamber C. The descending airflow that has not been discharged in this way may rise together with the gas raised by heat treatment at the periphery of the substrate W. Therefore, convection may occur between the substrate W and the injection unit 1100 in a right region of the lower space C12. In a similar manner, convection may occur in a left region of the lower space C12 due to rising and descending of the gas while the injection unit 1100 injects gas in a second transfer direction B2, which may be a direction toward the left side from the central portion CL.

As described above, a state in which the injection unit 1100 reciprocates from an upper portion of the substrate W and injects (supplies) the gas in the processing space C10 to form a downstream may be defined as a ‘second state T2.’

In the second state T2, since the injection unit 1100 reciprocates along the transport direction B from the top of the substrate W and supplies a gas, which may be a processing gas, a processing gas such as ozone may evenly contact the surface (upper surface) of the substrate W. In addition, as the gas (processing gas) circulates up and down in the first lower space C12a due to convection generated by reciprocating movement of the injection unit 1100, the processing gas may be evenly contacted over the entire surface of the substrate W, and an effect of decomposing the organic material may be improved, as described above.

In addition, even in the substrate processing apparatus 1A according to Example 2, the injection unit 1100 may continuously inject gas while the substrate W may be replaced with the new substrate W. At the same time, gas containing pollutants may be discharged through the gas-discharging unit C30, such that the inside of the processing chamber C may be maintained in a clean state.

In the substrate processing apparatuses 1, 1A according to the embodiments of the present disclosure as described above, the processing gas (gas) for removing the organic material may be configured to be in uniform contact with the entire surface of the substrate W, thereby improving an effect of removing the organic material on the substrate W.

In addition, when a number of substrates W are continuously heat-treated, the processing space C10 may be maintained at a high cleanliness to improve yield of the substrate W by continuously discharging the gas containing pollutants from the processing chamber C while the substrate W is replaced.

Although the substrate processing apparatus of the present disclosure has been described as an embodiment in which a photo process is applied, the present disclosure is not limited thereto, and it is obvious to those skilled in the art that the substrate is applied to various processes such as an etching process, a test process, a packaging process, and the like.

In a substrate processing apparatus according to embodiments of the present disclosure, processing gas (gas) for removing an organic material may be configured to uniformly contact an entire surface of a substrate, thereby improving an effect of removing the organic material on the substrate.

Additionally, when a plurality of substrates are continuously heated, it is useful in terms of homeostasis by discharging pollutant-containing gases from a processing chamber, during the substrates are replaced, to maintain high cleanliness in a process space, and quickly lowering a temperature in the chamber heated by irradiating UV to improve yield of the substrates.

While example embodiments have been illustrated and described above, it will be apparent to those skilled in the art that modifications and variations could be made without departing from the scope of the present disclosure as defined by the appended claims.

What is claimed is:

1. A substrate processing apparatus comprising:
a processing chamber having a processing space provided therein, and including a gas-supply unit introducing gas into the processing space;
a support portion disposed in the processing space and supporting a substrate;
a heating unit disposed to be spaced apart from an upper side of the support portion in the processing space, and including a lamp portion including a plurality of lamps heating the substrate, and a window disposed between the lamp portion and the support portion; and
a discharge unit disposed to reciprocate in one direction between the support portion and the heating unit, and suctioning and discharging gas in the processing space.

2. The substrate processing apparatus of claim 1, wherein the processing space includes an upper space in which the lamp portion is disposed, and a lower space separated from the upper space and in which the substrate is disposed therein to perform a processing process for the substrate, and
the window is disposed between the upper space and the lower space.

3. The substrate processing apparatus of claim 2, wherein the gas-supply unit is located between the discharge unit and the substrate, and is provided in two to be disposed on one side and the other side of the substrate, respectively.

4. The substrate processing apparatus of claim 1, wherein the discharge unit includes a body portion provided with a suction port suctioning the gas on a lower surface of the body portion, and a discharge line connected to the suction port and discharging the suctioned gas externally.

5. The substrate processing apparatus of claim 4, wherein the suction port is provided as a plurality of suction ports, and
the plurality of suction ports are disposed in a length direction of the body portion.

6. The substrate processing apparatus of claim 4, wherein the plurality of suction ports are disposed to form at least one row on the lower surface of the body portion.

7. The substrate processing apparatus of claim 5, wherein the plurality of suction ports have a diameter gradually increasing toward a center of the body portion.

8. The substrate processing apparatus of claim 4, wherein the suction port has an elongated slit shape extending in a length direction of the body portion.

9. The substrate processing apparatus of claim 4, wherein the body portion has a length, equal to or greater than a diameter of the substrate.

10. The substrate processing apparatus of claim 3, wherein the discharge unit suctions gas in the processing space, to form an upstream in the lower space, and
when the discharge unit suctions the gas, a new gas is introduced into the processing space through the gas-supply unit and convection is generated between the substrate and the upper space.

11. The substrate processing apparatus of claim 10, wherein the discharge unit reciprocates in the one direction between one side and other side of the substrate, and suctions and discharges the gas to remove foreign substances generated in heating the substrate.

12. The substrate processing apparatus of claim 1, wherein the discharge unit is provided as a plurality of discharge units, and
at least a portion of the plurality of discharge units individually reciprocates, and suctions and discharges the gas.

13. A substrate processing apparatus comprising:
a processing chamber having a processing space provided therein, and including a gas-discharging unit discharging gas in the processing space;
a support portion disposed in the processing space and supporting a substrate;
a heating unit disposed to be spaced apart from an upper side of the support portion in the processing space, and including a lamp portion including a plurality of lamps heating the substrate, and a window disposed between the lamp portion and the support portion; and
an injection unit disposed to reciprocate in one direction between the support portion and the heating unit, and injecting gas into the processing space.

14. The substrate processing apparatus of claim 13, wherein the processing space includes an upper space in which the lamp portion is disposed, and a lower space separated from the upper space and in which the substrate is disposed therein to perform a processing process for the substrate, and
the window is disposed between the upper space and the lower space.

15. The substrate processing apparatus of claim 14, wherein the gas-discharging unit is located between the injection unit and the substrate, and is provided in two to be disposed on one side and the other side of the substrate, respectively.

16. The substrate processing apparatus of claim 13, wherein the injection unit includes a body portion provided with an injection port injecting the gas on a lower surface of the body portion, and a supply line connected to the injection port and supplying the gas to the injection port.

17. The substrate processing apparatus of claim 16, wherein a plurality of the injection units are disposed to form at least one row on the lower surface of the body portion.

18. The substrate processing apparatus of claim 15, wherein the injection unit injects gas in the processing space, to form a downstream in the lower space, and
when the injection unit injects the gas, the gas in the processing space is discharged through the gas-discharging unit, and convection is generated between the substrate and the upper space.

19. The substrate processing apparatus of claim 18, wherein the injection unit reciprocates in the one direction between one side and other side of the substrate, and injects the gas in the processing space to discharge the gas to the gas-discharging unit, to remove by-products generated in heating the substrate.

20. A substrate processing apparatus comprising:
a processing chamber having a processing space provided therein, and including a gas-supply unit introducing gas into the processing space;
a support portion disposed in the processing space and supporting a substrate;
a heating unit disposed to be spaced apart from an upper side of the support portion in the processing space, and including a lamp portion including a plurality of lamps heating the substrate, and a window disposed between the lamp portion and the support portion;
a discharge unit disposed to reciprocate in one direction between the support portion and the heating unit to discharge gas into the processing space, and including a body portion having a length, equal to or greater than a diameter of the substrate, and provided with a plurality of injection ports injecting the gas on a lower surface of the body portion, a supply line connected to the plurality of injection ports and discharging suctioned gas externally, and a driver providing power reciprocating the body portion; and
a controller controlling the heating unit to heat the substrate, and controlling the discharge unit to discharge the gas in the processing space,
wherein the processing space includes an upper space in which the lamp portion is disposed, and a lower space separated from the upper space and in which the substrate is disposed therein to perform a processing process for the substrate, the upper space and the lower space are at least partially partitioned by the window,
the gas-supply unit is located between the discharge unit and the substrate, and at least two gas-supply units are provided to be disposed on both sides of the substrate,
the plurality of injection ports are disposed on a lower surface of the body to form at least one row, and
the controller controls:
during heating the substrate by the lamp portion, the discharge unit to be disposed and wait on one side of the substrate, and
when the heating of the substrate is completed, the discharge unit to reciprocate between both sides of the substrate in the one direction, suction gas to form an upstream in the lower space, and introduce a new gas into the processing space through the gas-supply unit, to generate convection between the substrate and the upper space to remove by-products generated during the heating of the substrate.
